(19) United States
(12) Patent Application Publication
(10) Pub. No.: US 2004/0146639 A1
(43) Pub. Date: Jul. 29, 2004

(54) Preparation of radiation image storage panel

(75) Inventor: Yuji Isoda, Kanagawa (JP)

Correspondence Address: SUGHRUE MION, PLLC, 2100 PENNSYLVANIA AVENUE, N.W., SUITE 800, WASHINGTON, DC, 20037, US

(73) Assignee: FUJI PHOTO FILM CO., LTD.

(21) Appl. No.: 10/702,769

(22) Filed: Nov. 7, 2003

(30) Foreign Application Priority Data
Nov. 7, 2002 (JP) 2002-324209

(51) Int. Cl. B05D 5/06; C23C 16/00

(52) U.S. Cl. 427/157; 427/65; 427/248.1

(57) ABSTRACT

In a method for preparing a radiation image storage panel comprising a support and a stimulable europium-activated cesium halide phosphor layer formed on the support by heating an europium-activated cesium halide phosphor or sources for production of the europium-activated cesium halide phosphor under reduced pressure to evaporate the phosphor or phosphor source and depositing the evaporated phosphor or phosphor source on a substrate, the deposition is preferably performed under the condition that a relationship between a molar ratio of europium to cesium in the deposited stimulable phosphor layer and a temperature of the substrate satisfies all of the formulas (1) to (3):

T≧867.24x^{0.4537} Formula (1)

T≧0.0985x^{-1.0587} Formula (2)

T≦485.4x²−760.75x+297.37 Formula (3)

in which T represents the temperature of the substrate in term of ° C., and x represents a molar ratio of europium to cesium in the deposited stimulable phosphor layer.

### FIELD OF THE INVENTION

The invention relates to an improvement of a method for preparing a radiation image storage panel favorably employable in a radiation image recording and reproducing method utilizing stimulated emission of a stimulable europium-activated cesium halide phosphor.

When the stimulable phosphor is exposed to radiation such as X-rays, it absorbs and stores a portion of the radiation energy. The stimulable phosphor then emits stimulated emission according to the level of the stored energy when the phosphor is exposed to electromagnetic wave such as visible light or infrared rays (i.e., stimulating light).

A radiation image recording and reproducing method utilizing the stimulable phosphor has been widely employed in practice. This method employs a radiation image storage panel comprising the stimulable phosphor, and comprises the steps of causing the stimulable phosphor of the storage panel to absorb radiation energy having passed through an object or having radiated from an object; sequentially exciting the stimulable phosphor with a stimulating light to emit stimulated light; and photoelectrically detecting the emitted light to obtain electric signals giving a visible radiation image. The storage panel thus treated is subjected to a step for erasing radiation energy remaining therein, and then stored for the use in the next recording and reproducing procedure. Thus, the radiation image storage panel can be repeatedly used.

The radiation image storage panel (often referred to as stimulable phosphor sheet) has a basic structure comprising a substrate (i.e., ort) and a stimulable phosphor layer provided thereon.

The stimulable phosphor layer is conventionally formed by coating a dispersion of phosphor particles in a binder solution on the substrate and drying the coated dispersion on the substrate, and therefore comprises a binder and phosphor particles dispersed therein.

It is desired that radiation image storage panels used in these methods have sensitivity as high as possible and further can give a reproduced radiation image of high quality (in regard of sharpness and graininess).

It is known that a radiation image storage panel having on a substrate a stimulable phosphor layer prepared by gas phase deposition such as vacuum vapor deposition or sputtering has a stimulable phosphor layer comprising multiple prismatic (or pillar-shaped) stimulable phosphor crystals standing on the substrate, and gives a reproduced radiation image with high sensitivity as well as high sharpness.

The radiation image storage panel comprising a support and a vapor deposited stimulable phosphor layer formed on the support is generally prepared by heating a stimulable phosphor or sources for production of the stimulable phosphor under reduced pressure to evaporate the phosphor or phosphor source and depositing the evaporated phosphor or phosphor source on a substrate.

In the above-described vapor deposition process, it is known that the substrate can be heated in order to deposit on the substrate a stimulable phosphor layer comprising prismatic phosphor crystals of good shape.

Japanese Patent Provisional Publication No. 10-62599 describes that in the vapor deposition procedure a substrate is preferably heated to 150 to 350° C. by controlling heating means. In the publication, only RbBr:Tl and BaFBr:Eu²⁺ are concretely described as the stimulable phosphors, and there is no mention with respect to a relationship between the temperature of the substrate and a concentration of an activator in the resulting phosphor in the stimulable phosphor layer.

It is also known that an europium-activated cesium halide phosphor can be favorably employed as the stimulable phosphor for the radiation image storage panel

### SUMMARY OF THE INVENTION

The present inventor has studied for providing a satisfactorily employable method for forming a stimulable phosphor layer of the europium-activated cesium halide (CsX:Eu, X is a halogen atom) phosphor on a substrate by gas phase deposition such as vapor deposition. According his study, it is not easy to form well shaped prismatic structures of the europium-activated cesium halide on the substrate. It is assumed that the crystal structure of the CsX:Eu comprising a monovalent cesium atom in the matrix component and a divalent or trivalent europium atom as the activator component is easily deformed because the divalent or trivalent europium atom ought to be incorporated into the monovalent cesium atom-containing matrix compound structure in the course of formation of the target stimulable phosphor layer on the substrate.

As a result of further study, the inventor has discovered that well aligned crystalline conditions of the europium-activated cesium halide phosphor crystals in the stimulable phosphor layer formed on the substrate by gas phase deposition can be attained with high reliability by controlling a relationship between the temperature of the substrate and a molar ratio of europium to cesium (Eu/Cs) in the deposited stimulable phosphor to satisfy the specific conditions. The stimulable phosphor layer formed on a substrate by gas phase deposition under the specific conditions is well fixed to the substrate, shows a high sensitivity, and gives a reproduced radiation image with high quality.

Accordingly, the present invention has an object to provide an improved method for preparing a radiation image storage panel employing a stimulable europium-activated cesium halide phosphor which shows high resistance to separation of the stimulable phosphor layer from the substrate (or support), shows a high sensitivity, and yields a reproduced radiation image with high quality.

The present invention resides in a method for preparing a radiation image storage panel comprising a support and a stimulable europium-activated cesium halide phosphor layer formed on the support by heating an europium-activated cesium halide phosphor or sources for production of the europium-activated cesium halide phosphor under reduced pressure to evaporate the phosphor or phosphor source and deposit the evaporated phosphor or phosphor source on a substrate, wherein the deposition is performed under the condition that a relationship between a molar ratio of europium to cesium in the deposited stimulable phosphor layer and a temperature of the substrate satisfies all of the following formulas (1) to (3):

T≧867.24x^{0.4537} Formula (1)

T≧0.0985x^{-1.0587} Formula (2)

T≦485.4x²−760.75x+297.37 Formula (3)

in which T represents the temperature of the substrate in term of ° C., and x represents a molar ratio of europium to cesium in the deposited stimulable phosphor layer.

Preferred embodiments of the invention are described below:

(1) The evaporation and deposition are performed at a pressure of not higher than 1 Pa.

(2) The evaporation and deposition are performed at a pressure of not higher than 0.1 Pa.

(3) The evaporation and deposition are performed at a pressure of 0.1 Pa to 5 Pa.

(4) The evaporation and deposition are performed at a pressure of 0.1 Pa to 2 Pa.

(5) The relationship between a molar ratio of europium to cesium in the deposited stimulable phosphor layer and a temperature of the substrate satisfies all of the following formulas (4) to (7):

T≦175.14x^{-0.0682} Formula (4)

T≦0.028x^{-1.308} Formula (5)

T≧−63745x²−3581.4x+304.61 Formula (6)

T≦23.844 Ln(x)+265.01 Formula (7)

in which T and x have the same meanings as defined in claim 1.

(6) The substrate has an embossed surface.

(7) The embossed surface has a pattern having a pitch of not more than 15 μm.

(8) The evaporation is performed by evaporating an evaporation source comprising cesium halide and an evaporation source comprising an europium compound simultaneously.

(9) The deposition is performed by depositing on the substrate first a cesium halide and second a stimulable europium-activated cesium halide phosphor thereon.

(10) The stimulable europium-activated cesium halide phosphor has the formula (I):

CsX.aM^{II}X′₂·bM^{III}X″₃:zA (I)

in which M^{II} is at least one alkaline earth metal element or divalent metal element selected from the group consisting of Be, MB, Ca, Sr, Ba, Ni, Cu, Zn and Cd; Mi is at least one rare earth element or trivalent metal element selected from the group consisting of Sc, Y, La, Ce, Pr, Nd, Pm, Sm, Eu, Gd, Tb, Dy, Ho, Er, Tm, Yb, Lu, Al, Ga and In; each of each of X, X′ and X″ independently is at least one halogen selected from the group consisting of F, Cl, Br and I; A is at least one rare earth element or metal element selected from the group consisting of Y, Ce, Pr, Nd, Sm, Eu, Gd, Tb, Dy, Ho, Er, Tm, Yb, Lu, Mg, Cu, and Bi; and a, b and z are numbers satisfying the conditions of 0≦a<0.5, 0≦b<0.5 and 5×10⁻⁴≦z≦7×10⁻², respectively.

(11) In the formula (I), X is Br.

### BRIEF DESCRIPTION OF DRAWINGS

FIG. 1 is a graph showing the satisfactory area of the relationship between a temperature (T: IC) of a substrate and a concentration x of Eu activator (in term of Eu/Cs, molar ratio) in which numbers 1, 2 and 3 means formulas (1), (2) and (3), respectively.

### DETAILED DESCRIPTION OF INVENTION

The radiation image storage panel of the invention is preferably prepared by a vapor deposition method. Details of the vapor deposition method are described below.

The support (i.e., Substrate) preferably is a sheet of quartz glass, sapphire, metal (e.g., aluminum, iron, tin, or chromium) or heat-resistant resin (e.g., aramide resin). The support may have an embossed surface (pitch of the embossing pattern preferably is in a range of 1 to 10 μm) or a surface having concaves and/or convexes. Top surfaces of protrusions of the embossing pattern can give bases for growing the phosphor crystals.

On the substrate can be placed a light reflecting layer such as a layer containing a titanium dioxide or a light absorbing layer such as a layer containing carbon black.

On the substrate or the auxiliary layer, a phosphor matrix compound layer can be formed, preferably, by vapor deposition.

The phosphor matrix compound layer preferably comprises a matrix compound of a stimulable phosphor which is later formed on the phosphor matrix compound layer.

The stimulable phosphor employed in the method of the invention is an europium-activated cesium halide phosphor which preferably has the above-identified formula (I).

The evaporation source can comprise an europium-activated cesium halide compound or a mixture of an europium compound and cesium halide. In the vapor deposition procedure, the europium compound and cesium halide can be separately placed so as to evaporate the europium compound-containing evaporation source and the cesium halide evaporation source independently with controlling heat energy applied to each of these evaporation sources.

In the phosphor or phosphor source, the europium compound preferably comprise a divalent europium (Eu²⁺) compound and a trivalent (Eu³⁺) compound. The europium compound preferably is EuBrₓ in which x preferably satisfies the condition of 2.0≦x≦2.3. The preferred EuBr₂ from which oxygen content is reduced by melting procedure can be favorably employed. It is preferred that the europium compound contains the divalent europium compound as much as possible, at least 70%.

The evaporation source preferably is in the form of a tablet having a water content of not more than 0.5 wt %. Moreover, the evaporation source preferably has a relative density of 80% to 95%, more preferably 90% to 96%. The relative density means a value obtained by dividing a density of the evaporation source by the inherent density of the corresponding material. The evaporation source of a high relative density can be evaporated uniformly and then is effective to deposit a stimulable phosphor layer of a uniform thickness.

On the substrate, a stimulable CsX:Eu phosphor layer is formed by vaporization of an evaporation source and deposition of the produced vapor on the substrate.

The vaporization of the evaporation source and deposition of the produced vapor can be performed in a vacuum evaporation apparatus comprising a vacuum chamber equipped with a vacuum pump, a supporting plate for evaporation source, heating means, and a supporting means for the substrate on which the vapor is to be deposited.

For performing the vacuum evaporation, the evaporation source is placed directly on the supporting plate or placed in a crucible or dish which is then placed on the supporting plate. A number of evaporation sources can be employed simultaneously in the vacuum evaporation. The substrate is attached to the supporting means in the position over the evaporation sources.

For the preparation of the phosphor layer on a substrate, it is preferred to employ two or more evaporation sources such as a combination of an evaporation source (such as in the form of tablet) comprising a matrix component and an evaporation source (such as in the form of tablet) comprising an activator component.

In the evaporation procedure, an evaporation source or evaporation sources comprising a matrix component and an activator component independently or in combination, and a substrate can be first set in a vacuum evaporation apparatus. The substrate is placed perpendicularly to the direction in which the vapor comes out of the source. The apparatus is then evacuated to give an inner pressure of 1×10⁻⁵ to 1×10⁻² Pa for electron beam evaporation or 0.1 to 5 Pa (preferably 0.1 to 3 Pa) for resistance heating evaporation. An inert gas such as Ar gas or Ne gas is preferably incorporated into the apparatus.

The evaporation source are heated by applying an electron beam or heating a resistance heating means, to form a prismatic stimulable phosphor crystalline layer on the substrate.

In the electron beam evaporation, an electron beam generated by an electron gun is applied auto the evaporation source. The accelerating voltage of electron beam preferably is in the range of 1.5 kV to 5.0 kV. By applying the electron beam, the evaporation source of matrix component and activator element is heated, vaporized, and deposited on the substrate. In the resistance heating evaporation, the evaporation sources are heated by supplying electric energy to the resistance heating means. The deposition rate generally is in the range of 0.1 to 1,000 μm/min., preferably in the range of 1 to 100 μm/min. The substrate is heated during the deposition procedure by controlling its temperature under the condition to satisfy the relationship with the Eu/Cs molar ratio of the stimulable phosphor layer to be deposited on the substrate.

After the procedure for forming the stimulable phosphor layer on the substrate is complete, the resulting layer can be subjected to heat treatment (annealing treatment).

The stimulable phosphor layer preferably has a thickness of 50 to 1,000 μm, more preferably 200 to 700 μm.

The formed phosphor layer comprises prismatic stimulable phosphor crystals which are aligned almost perpendicularly to the substrate. Thus formed phosphor layer comprises only the stimulable phosphor with no binder, and there are produced cracks extending the depth direction in the phosphor layer.

As described above, the vacuum evaporation or deposition method is not restricted to the electron beam-evaporating method, and various known methods such as resistance-heating method, sputtering method, and CVD method can be used.

It is preferred to place a transparent protective film on the surface of the stimulable phosphor layer, so as to ensure good handling of the radiation image storage panel in transportation and to avoid deterioration. The protective film preferably is transparent. Further, for protecting the storage panel from chemical deterioration and physical damage, the protective film preferably is chemically stable, physically strong, and of high moisture proof.

The protective film can be provided by coating the stimulable phosphor film with a solution in which an organic polymer (e.g., cellulose derivatives, polymethyl methacrylate, fluororesins soluble in organic solvents) is dissolved in a solvent, by placing a beforehand prepared sheet for the protective film (e.g., a film of organic polymer such as polyethylene terephthalate, a transparent glass plate) on the phosphor film with an adhesive, or by depositing vapor of inorganic compounds on the phosphor film.

Various additives may be dispersed in the protective film. Examples of the additives include light-scattering fine particles (e.g., particles of magnesium oxide, zinc oxide, titanium dioxide and alumina), a slipping agent (e.g., powders of perfluoroolefin resin and silicone resin) and a crosslinking agent (e.g., polyisocynate). The thickness of the protective film generally is in the range of about 0.1 to 20 μm (if the film is made of polymer material) or in the range of about 100 to 1,000 μm (if the film is made of inorganic material such as silicate glass). For enhancing the resistance to stain, a fluororesin layer is preferably provided on the protective film. The fluororesin layer can be form by coating the surface of the protective film with a solution in which a fluororesin is dissolved or dispersed in an organic solvent, and drying the coated solution. The fluororesin may be used singly, but a mixture of the fluororesin and a film-forming resin can be employed. In the mixture, an oligomer having polysiloxane structure or perfluoroalkyl group can be further added. In the fluororesin layer, fine particle filler may be incorporated to reduce blotches caused by interference and to improve the quality of the resultant image. The thickness of the fluororesin layer is generally in the range of 0.5 to 20 μm. For forming the fluororesin layer, additives such as a crosslinking agent, a film-hardening agent and an anti-yellowing agent can be used. In particular, the crosslinking agent is advantageously employed to improve durability of the fluororesin layer.

Thus, a representative radiation image storage panel of the invention can be prepared. The storage panel of the invention may be in known various structures. For example, in order to improve the sharpness of the resultant image, at least one of the films may be colored with a colorant which does not absorb the stimulated emission but the stimulating rays.

The present invention is further described by the following examples.

### EXAMPLE 1

### Two Source Evaporation (Electron Beam Radiation)

(1) Starting Materials

Powdery cesium bromide (CsBr, purity: 4N or higher) and powdery europium bromide (EuBrₓ, x approx. 2.2, purity: not lower than 3N) were employed as the starting materials. The analysis of each starting material by ICP-MS method (inductively coupled plasma spectroscopy mass spectroscopy) revealed that each of alkali metals other than Cs (Li, Na, K, Rb) and each of alkaline earth metals (Mg, Ca, Sr, Ba) were present in the cesium bromide in amounts of less than 10 ppm and less than 2 ppm, respectively, and each of rare earth elements other than Ea and each of other elements were present in the europium bromide in amounts of less than 20 ppm and less than 10 ppm, respectively.

Since both starting materials were highly hygroscopic, they were stored in a desiccator under dry atmosphere showing a dew point of lower than −20° C., and taken out just before the following preparation was made.

(2) Preparation of CsBr Evaporation Source

The powdery CsBr (75 g) was placed in a powder molding zirconia die (inner diameter: 35 mm) and compressed in a powder molding press (Tablepress TB-5 type, NPA System Co., Ltd.) at a pressure of 50 MPa, to produce a tablet (diameter: 35 mm, thickness. 20 mm). The pressure applied to the powdery CsBr was approx. 40 MPa. The tablet was dried in a vacuum drying apparatus at 200° C., for 2 hours. The dried tablet had a density of 3.9 g/cm³ and a water content of 0.3 wt. %.

(3) Preparation of EuBrₓ Evaporation Source

The powdery EuBrₓ (x=approx. 2.2, 25 g) was placed in a powder molding zirconia die (inner diameter: 25 mm) and compressed in the power molding press at a pressure of 50 MPa, to produce a tablet (diameter: 25 mm, thickness: 10 mm) the pressure applied to the powdery CsBr was approx. 80 MPa. The tablet was placed in a vacuum drying apparatus and heated to 200° C. for 2 hours in vacuo. The produced tablet had a density of 5.1 g/cm³, and a water content of 0.5 wt. %.

(4) Formation of Stimulable Phosphor Layer

A glass substrate having an embossed surface (diameter and height of each protrusion: 5 μm and 5 μm, respectively, pitch between adjoining protrusions: 2 μm) was washed successively with an aqueous alkaline solution, purified water, and isopropyl alcohol, and then mounted to a substrate holder within an evaporation apparatus under the condition that the embossed surface faced the evaporation sources. In the apparatus, the CsBr tablet and EuBrₓ tablet were placed in the predetermined sites. Subsequently, the apparatus was evacuated using a combination of a rotary pump, mechanical booster, and turbo molecular pump to reach 1×10⁻³ Pa (in the presence of argon gas).

In the apparatus, the substrate was heated to 200° C. (measured temperature) by means of a sheath heater placed on the back side of the substrate. An electron beam from an electron gun (accelerating voltage: 4.0 kV) was applied onto the tablets, to deposit a stimulable CsBr:Eu phosphor layer at a deposition rate of 4 μm. In the procedure of application of the electron beams, the emission currents supplied to the electron guns were so controlled that a molar ratio of Eu/Cs in the phosphor layer is adjusted to 0.003/1. The partial pressure of water in the apparatus was 4.0×10⁻³ Pa.

After the evaporation-deposition procedure was complete, the inner pressure was returned to atmospheric pressure, and the substrate was taken out of the apparatus. The substrate having the deposited phosphor film was placed on a quartz boat an heated at 200° C. for 2 hours in the center of a tube furnace under nitrogen gas atmosphere. Before and during the heat treatment, the center of the tube furnace was evacuated by means of a rotary pump to reach approx. 10 Pa, so that water adsorbed on the deposited film would be removed. Subsequently, the substrate and the deposited film was cooled in vacuo, and thus cooled substrate was then taken out of the tube furnace. On the substrate, a deposited stimulable phosphor layer (thickness: approx. 400 μm, area: 30 cm×30 cm) consisting of prismatic phosphor crystals aligned densely and perpendicularly was formed.

Thus, a radiation image storage panel of the invention having a substrate and a deposited phosphor layer was prepared.

The above-mentioned procedures were repeated with variation of the substrate temperature between 30 to 350° C., and variation of the Eu/Cs molar ration between 0.0003/1 to 0.03/1, to prepare a great number of radiation image storage panels.

### Evaluation of Radiation Image Storage Panel

The resulting radiation image storage panels were evaluated in their adhesion between the substrate and the stimulable phosphor layer, conditions of the prismatic crystals, and sensitivity, according to the below-mentioned procedures.

(1) Conditions of Prismatic Crystals

The radiation image storage panel was sectioned in the depth direction. The section face was coated with gold by ion sputtering, and observed by a scanning electron microscope (JSM-5400, available from Nippon Electron Co., Ltd. The results of the microscopic observation were examined by five members to give a rank (highest point: 7) of the conditions of the prismatic phosphor crystals. The average of ranks given by the five members is set forth in Table 1. The rank of acceptable conditions is 1.5 or more.

(2) Sensitivity

Each radiation image storage panel was encased in a room light-shielding cassette and then exposed to X-rays (26 mR). Subsequently, the storage panel was taken out of the cassette and scanned with LD laser beam (wavelength: 650 nm). The stimulated emission was detected by a photomultiplier to measure the luminance of stimulated emission emitted from each storage panel. The measured luminance is set forth in Table 2 in terms of a relative value. The relative value for an acceptable radiation image storage panel is 100 or more.

(3) Adhesion (Peel Strength)

An adhesive layer of an adhesive tape was pressed on the stimulable phosphor layer, the adhesive tape was peeled from the phosphor layer, and the phosphor layer remaining on the substrate was observed to examine a surface area of the phosphor layer separated from the substrate. The evaluation was made by the following criteria: point 4 for non-peeling.

The results are set forth in Table 3.

The acceptable radiation image storage panel should have point 2 or more.

TABLE 1

| Temp. (° C.) | Eu/Cs molar ratio | | | | |
|---|---|---|---|---|---|
| of Substrate | 3 × 10⁻⁴ | 1 × 10⁻³ | 3 × 10⁻³ | 1 × 10⁻² | 3 × 10⁻² |
| 30 | 1.8 | 1.6 | 1 | 1 | 1 |
| 50 | 4.4 | 2.6 | 1.6 | 1.2 | 1 |
| 100 | 5.6 | 5.2 | 3.4 | 1.6 | 1 |
| 150 | 6.2 | 5.8 | 4.6 | 3.4 | 1 |
| 200 | 6.6 | 6.6 | 6.4 | 4.6 | 1.6 |
| 250 | 6.8 | 6.6 | 6.6 | 5.4 | 2.6 |
| 300 | 6.8 | 6.8 | 6.8 | 6.4 | 2.8 |
| 350 | 7 | 6.8 | 6.8 | 6.4 | 4 |

TABLE 2

| Temp. (° C.) | Eu/Cs molar ratio | | | | |
|---|---|---|---|---|---|
| of Substrate | 3 × 10⁻⁴ | 1 × 10⁻³ | 3 × 10⁻³ | 1 × 10⁻² | 3 × 10⁻² |
| 30 | 56 | 59 | 72 | 83 | 120 |
| 50 | 57 | 72 | 80 | 78 | 123 |
| 100 | 58 | 98 | 325 | 62 | 114 |
| 150 | 59 | 202 | 515 | 101 | 106 |
| 200 | 61 | 332 | 845 | 102 | 104 |
| 250 | 67 | 339 | 685 | 144 | 102 |
| 300 | 66 | 340 | 683 | 177 | 64 |
| 350 | 53 | 57 | 270 | 175 | 58 |

TABLE 3

| Temp. (° C.) | Eu/Cs molar ratio | | | | |
|---|---|---|---|---|---|
| of Substrate | 3 × 10⁻⁴ | 1 × 10⁻³ | 3 × 10⁻³ | 1 × 10⁻² | 3 × 10⁻² |
| 30 | 4 | 4 | 4 | 2 | 2 |
| 50 | 4 | 4 | 4 | 2 | 2 |
| 100 | 4 | 4 | 4 | 2 | 2 |
| 150 | 4 | 4 | 3 | 2 | 2 |
| 200 | 4 | 3 | 3 | 2 | 2 |
| 250 | 3 | 3 | 2 | 2 | 1 |
| 300 | 2 | 3 | 1 | 1 | 1 |
| 350 | 1 | 1 | 1 | 1 | 1 |

### EXAMPLE 2

### Two Source Evaporation (Electron Beam Radiation, Matrix Compound Subbing Layer was for)

(1) Starting Materials

The same starting materials as in Example 1 were employed.

(2) Preparation of CsBr Evaporation Source

A CsBr tablet was prepared in the same manner as in Example 1.

(3) Preparation of EuBrₓ Evaporation Source

A table of EuBrₘ (m=2.2) was prepared in the same manner as in Example 1.

(4) Formation of Stimulable Phosphor Layer

A synthetic quartz substrate was washed successively with an aqueous alkaline solution, purified water, and isopropyl alcohol, and then mounted to a substrate holder within an evaporation apparatus under the condition that the embossed surface faced the evaporation sources in the apparatus, the CsBr tablet and EuBrₓ tablet were placed in the predetermined sites. Subsequently, the apparatus was evacuated using a combination of a rotary pump, mechanical booster, and turbo molecular pump to reach 1×10⁻³ Pa (in the presence of argon gas).

In the apparatus, the substrate was heated to 200° C. (measured temperature) by means of a sheath heater placed on the back side of the substrate. An electron beam from an electron gun (accelerating voltage: 4.0 kV) was applied onto the tablets, to deposit a stimulable CsBr:Eu phosphor layer at a deposition rate of 4 μm. In the procedure of application of the electron beams, the emission currents supplied to the electron guns were so controlled that a molar ratio of Eu/Cs in the phosphor layer is adjusted to 0.003/1. The partial pressure of water in the apparatus was 4.0×10.3 Pa.

After the evaporation-deposition procedure was complete, the substrate having the deposited phosphor layer was subjected to the heat treatment in the same manner as in Example 1. On the substrate, a deposited stimulable phosphor layer (thickness: approx. 400 μm, area: 30 cm×30 cm) consisting of prismatic phosphor crystals aligned densely and perpendicularly was formed.

Thus, a radiation image storage panel of the invention having a substrate and a deposited phosphor layer was prepared.

The above-mentioned procedures were repeated with variation of the substrate temperature between 30 to 350° C., and variation of the Eu/Cs molar ration between 0.0003/1 to 0.03/1, to prepare a great er of radiation image storage panels.

### Evaluation of Radiation Image Storage Panel

The resulting radiation image storage panels were evaluated in their adhesion between the substrate and the stimulable phosphor layer, conditions of the prismatic crystals, and sensitivity, according to the aforementioned procedures.

The results are set forth in Tables 4, 5 and 6.

The acceptable radiation image storage panel should have point 2 or more.

TABLE 4

| Temp. (° C.) | Eu/Cs molar ratio | | | | |
|---|---|---|---|---|---|
| of Substrate | 3 × 10⁻⁴ | 1 × 10⁻³ | 3 × 10⁻³ | 1 × 10⁻² | 3 × 10⁻² |
| 30 | 1.6 | 1.6 | 1.2 | 1 | 1 |
| 50 | 3.6 | 2.8 | 1.6 | 1.4 | 1 |
| 100 | 4.6 | 4 | 3.6 | 1.8 | 1 |
| 150 | 5.4 | 4.8 | 4.2 | 2.4 | 1.2 |
| 200 | 5.8 | 5.2 | 4.8 | 3 | 1.6 |
| 250 | 6.4 | 5.8 | 5.6 | 3.4 | 1.8 |
| 300 | 6.6 | 6 | 5.8 | 3.8 | 2.4 |
| 350 | 6.8 | 6.4 | 5.8 | 4 | 3.2 |

TABLE 5

| Temp. (° C.) | Eu/Cs molar ratio | | | | |
|---|---|---|---|---|---|
| of Substrate | 3 × 10⁻⁴ | 1 × 10⁻³ | 3 × 10⁻³ | 1 × 10⁻² | 3 × 10⁻² |
| 30 | 52 | 60 | 60 | 60 | 54 |
| 50 | 53 | 62 | 65 | 61 | 56 |
| 100 | 54 | 95 | 125 | 92 | 61 |
| 150 | 55 | 185 | 194 | 168 | 92 |
| 200 | 57 | 249 | 492 | 205 | 139 |
| 250 | 56 | 170 | 201 | 151 | 102 |
| 300 | 54 | 73 | 80 | 70 | 64 |
| 350 | 53 | 62 | 68 | 56 | 52 |

TABLE 6

| Temp. (° C.) | Eu/Cs molar ratio | | | | |
|---|---|---|---|---|---|
| of Substrate | 3 × 10⁻⁴ | 1 × 10⁻³ | 3 × 10⁻³ | 1 × 10⁻² | 3 × 10⁻² |
| 30 | 4 | 3 | 3 | 3 | 3 |
| 50 | 4 | 3 | 3 | 3 | 2 |
| 100 | 4 | 3 | 3 | 3 | 2 |
| 150 | 4 | 3 | 3 | 2 | 2 |
| 200 | 4 | 3 | 3 | 2 | 2 |
| 250 | 4 | 3 | 2 | 2 | 1 |
| 300 | 2 | 2 | 1 | 1 | 1 |
| 350 | 1 | 1 | 1 | 1 | 1 |

The results of evaluation (conditions of the prismatic crystals, sensitivity, and adhesion) obtained in Examples 1 and 2 was reviewed and the total evaluation was made on each radiation image storage panel by the following criteria:

AA: Prominently excellent

A: Good, and acceptable for practical use

C: Poor, and non-acceptable for practical use

The results of total evaluation are set forth in Table 7.

TABLE 7

| Temp. (° C.) | Eu/Cs molar ratio | | | | |
|---|---|---|---|---|---|
| of Substrate | 3 × 10⁻⁴ | 1 × 10⁻³ | 3 × 10⁻³ | 1 × 10⁻² | 3 × 10⁻² |
| 30 | C | C | C | C | C |
| 50 | C | C | C | C | C |
| 100 | C | C | A | A | C |
| 150 | C | A | AA | A | C |
| 200 | C | AA | AA | A | A |
| 250 | C | A | A | A | A |
| 300 | C | C | C | C | C |
| 350 | C | C | C | C | C |

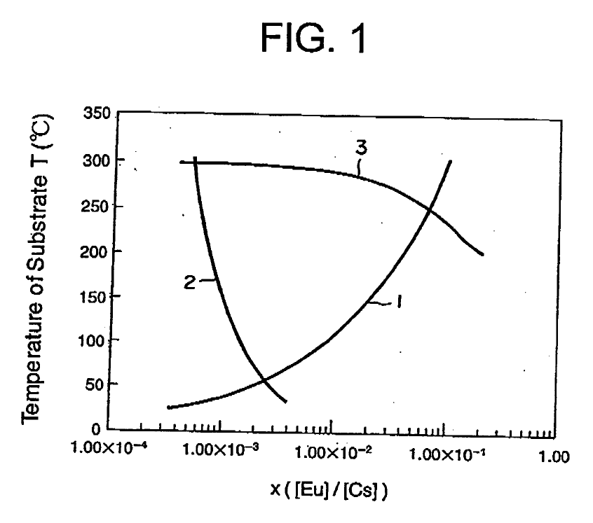

The radiation image storage panels prepared by the present invention are given the marks A or AA. These radiation image storage panels were pr e d under the condition of the relationship between the temperature of a substrate and the molar ratio of Eu/Cs satisfying all of the aforementioned formulas (1), (2) and (3). The area enclosed with these formulas are graphically illustrated in FIG. 1 in which the curve 1, 2 and 3 correspond to the formula (1), (2), and (3), respectively. The formula (1) was determined mainly from the viewpoint of conditions of prismatic crystals, the formula (2) was determined mainly from the viewpoint of sensitivity, and the formula (3) was determined mainly from the viewpoint of adhesion.

### EXAMPLE 3

### Two Source Evaporation (Resistance Heating, Matrix Compound Subbing Layer was Formed)

(1) Starting Materials

The same starting materials as in Example 0.1 were employed.

(2) Preparation of CsBr Evaporation Source

A CsBr tablet was prepared in the same manner as in Example 1.

(3) Preparation of EuBrₓ Evaporation Source

A table of EuBr₂ was prepared by a melting procedure in Br gas.

(4) Formation of Stimulable Phosphor Layer

Each evaporation source was placed on a resistance heating means having plural heating sites in an evaporation apparatus, according to the known resistance heating method. The evaporation apparatus was evacuated to a vacuum level of 1 Pa (in the presence of Ar gas). The evaporation rates were controlled by varying supply of electric energy to each evaporation source to deposit successively a matrix compound subbing layer (CsBr layer) and a stimulable CsBr:Eu phosphor layer.

After the evaporation-deposition procedure was complete, the substrate having the deposited phosphor layer was subjected to the heat treatment in the same manner as in Example 1. On the substrate, a deposited stimulable phosphor layer (thickness: approx. 400 μm, area: 30 cm×30 cm) consisting of prismatic phosphor crystals aligned densely and perpendicularly was formed.

Thus, a radiation image storage panel of the invention having a substrate and a deposited phosphor layer was prepared.

The above-mentioned procedures were repeated with variation of the substrate temperature between 100 to 300° C., and variation of the Eu/Cs molar ration between 0.0003/1 to 0.03/1, to prepare a great number of radiation image storage panels.

TABLE 8

| Temp. (° C.) | Eu/Cs molar ratio | | | | |
|---|---|---|---|---|---|
| of Substrate | 3 × 10⁻⁴ | 1 × 10⁻³ | 3 × 10⁻³ | 1 × 10⁻² | 3 × 10⁻² |
| 100 | 1.8 | 1.8 | 1.6 | 1 | 1 |
| 150 | 6.6 | 6 | 4.8 | 1.4 | 1 |
| 200 | 7 | 6.6 | 6.4 | 3.4 | 1.4 |
| 250 | 7 | 6 | 5.6 | 3.6 | 1.8 |
| 300 | 6.2 | 4.6 | 2.4 | 2 | 2 |

TABLE 9

| Temp. (° C.) | Eu/Cs molar ratio | | | | |
|---|---|---|---|---|---|
| of Substrate | 3 × 10⁻⁴ | 1 × 10⁻³ | 3 × 10⁻³ | 1 × 10⁻² | 3 × 10⁻² |
| 100 | 32 | 93 | 475 | 364 | 103 |
| 150 | 43 | 640 | 1420 | 555 | 141 |
| 200 | 85 | 1980 | 2750 | 1120 | 183 |
| 250 | 73 | 2030 | 2630 | 1030 | 122 |
| 300 | 68 | 1010 | 970 | 900 | 70 |

TABLE 10

| Temp. (° C.) | Eu/Cs molar ratio | | | | |
|---|---|---|---|---|---|
| of Substrate | 3 × 10⁻⁴ | 1 × 10⁻³ | 3 × 10⁻³ | 1 × 10⁻² | 3 × 10⁻² |
| 100 | 4 | 4 | 4 | 3 | 2 |
| 150 | 4 | 4 | 4 | 3 | 2 |
| 200 | 4 | 4 | 4 | 3 | 1 |
| 250 | 1 | 1 | 3 | 2 | 1 |
| 300 | 1 | 1 | 1 | 1 | 1 |

The results of evaluation (conditions of the prismatic crystals, sensitivity, and adhesion) obtained in Example 3 was reviewed and the total evaluation was made on each radiation image storage panel by the following criteria:

AA: Prominently excellent

A: Good, and acceptable for practical use

C: Poor, and non-acceptable for practical use

The results of total evaluation are set forth in Table 11.

TABLE 11

| Temp. (° C.) | Eu/Cs molar ratio | | | | |
|---|---|---|---|---|---|
| of Substrate | 3 × 10⁻⁴ | 1 × 10⁻³ | 3 × 10⁻³ | 1 × 10⁻² | 3 × 10⁻² |
| 100 | C | C | A | A | C |
| 150 | C | A | AA | A | C |
| 200 | C | AA | AA | A | A |
| 250 | C | AA | A | A | A |
| 300 | C | C | C | C | C |

The radiation image storage panels prepared by the present invention are given the marks A or AA. These radiation image storage panels were prepared under the condition of the relationship between the temperature of a substrate and the molar ratio of Eu/Cs satisfying all of the aforementioned formulas (1), (2) and (3). The area enclosed with these formulas are graphically illustrated in FIG. 1 in which the curve 1, 2 and 3 correspond to the formula (1), (2), and (3), respectively. The formula (1) was determined mainly from the viewpoint of conditions of prismatic crystals, the formula (2) was determined mainly from the viewpoint of sensitivity, and the formula (3) was determined mainly from the viewpoint of adhesion.

Particularly, the radiation image storage panels given the marks AA are preferred, and these storage panels are prepared by the gas phase deposition conditions defined by the aforementioned (4) to (7).

What is claimed is:

1. A method for preparing a radiation image storage panel comprising a support and a stimulable europium-activated cesium halide phosphor layer formed on the support by heating an europium-activated cesium halide phosphor or sources for production of the europium-activated cesium halide phosphor under reduced pressure to evaporate the phosphor or phosphor source and deposit the evaporated phosphor or phosphor source Ca a substrate, wherein the deposition is performed under the condition that a relationship between a molar ratio of europium to cesium in the deposited stimulable phosphor layer and a temperature of the substrate satisfies all of the following formulas (1) to (3):
T≧867.24x^{0.4537} Formula (1)
T≧0.0985x^{-1.0587} Formula (2)
T≦485.4x²−760.75x+297.37 Formula (3)
in which T represents the temperature of the substrate in term of ° C., and x represents a molar ratio of europium to cesium in the deposited stimulable phosphor layer.

2. The method of claim 1, wherein the evaporation and deposition are performed at a pressure of not higher than 1 Pa.

3. The method of claim 2, wherein the evaporation and deposition are performed at a pressure of not higher than 0.1 Pa.

4. The method of claim 1, wherein the evaporation and deposition are performed at a pressure of 0.1 Pa to 5 Pa.

5. The method of claim 4, wherein the evaporation and deposition are performed at a pressure of 0.1 Pa to 2 Pa.

6. The method of claim 4, wherein the relationship between a molar ratio of europium to cesium in the deposited stimulable phosphor layer and a temperature of the substrate satisfies all of the following formulas (4) to (7):
T≦175.14x^{-0.0682} Formula (4)
T≦0.028x^{-1.308} Formula (5)
T≧−63745x²−3581.4x+304.61 Formula (6)
T≦23.844 Ln(x)+265.01 Formula (7)
in which T and x have the same meanings as defined in claim 1.

7. The method of claim 1, wherein the substrate has an embossed surface.

8. The method of claim 7, wherein the embossed surface has a pattern having a pitch of not more than 15 μm.

9. The method of claim 1, wherein the evaporation is performed by evaporating an evaporation source comprising cesium halide and an evaporation source comprising an europium compound simultaneously.

10. The method of claim 1, wherein the deposition is performed by depositing on the substrate first a cesium halide and second a stimulable europium-activated cesium halide phosphor thereon.

11. The method of claim 1, wherein the stimulable europium-activated cesium halide phosphor has the formula (I):
CsX.aM^{II}X′₂.bM^{III}X″₃:zA (I)
in which M^{II} is at least one alkaline earth metal element or divalent metal element selected from the group consisting of Be, Mg, Ca, Sr, Ba, Ni, Cu, Zn and Cd; M^{III} is at least one rare earth element or trivalent metal element selected from the group consisting of Sc, Y, La, Ce, Pr, Nd, Pm, Sm, Eu, Gd, Tb, Dy, Ho, Er, Tm, Yb, Lu, Al, Ga and In; each of each of X, X′ and X″ independently is at least one halogen selected from the group consisting of F, Cl, Br and I; A is at least one rare earth element or metal element selected from the group consisting of Y, Ce, Pr, Nd, Sm, Eu, Gd, Tb, Dy, Ho, Er, Tm, Yb, Lu, Mg, Cu, and Bi; and a, b and z are numbers satisfying the conditions of 0≦a<0.5, 0≦b<0.5 and 5×10⁻⁴≦z≦7×10⁻², respectively.

12. The method of claim 11, wherein X is Br.
